(19) United States
(12) Patent Application Publication
(10) Pub. No.: US 2026/0223497 A1
(43) Pub. Date: Jul. 30, 2026

(54) MICROLENS FOR MICRO-LED AND MICRO-LED CHIP

(71) Applicant: Hue Inc., Shanghai (CN)

(72) Inventors: Feng Feng, Shanghai (CN); Jian Guo, Shanghai (CN)

(73) Assignee: Hue Inc., Shanghai (CN)

(21) Appl. No.: 19/454,340

(22) Filed: Jan. 20, 2026

(30) Foreign Application Priority Data
Jan. 26, 2025 (CN) 202510125208.4

(51) Int. Cl. H10H 20/855; H10H 20/832; H10H 20/852; H10H 29/24

(52) U.S. Cl. CPC H10H 20/855; H10H 20/835; H10H 20/852; H10H 29/24

(57) ABSTRACT

Disclosed is a microlens for a micro-LED, including: a spacer portion arranged between a light-emitting mesa of the micro-LED and a lens portion to adjust the position of the focal point of the lens portion relative to the light-emitting mesa; and a lens portion arranged on the spacer portion to shape light from the light-emitting mesa, where the diameter of the upper surface of the light-emitting mesa facing the microlens is n, the spherical height of the lens portion is a x n, the radius of curvature is m, the height of the spacer portion is b x n, and the width of the spacer portion is c x n, wherein a, b, c, m, and n are all positive numbers, wherein: 1.2 ≤ a ≤ 1.6; 0.2 ≤ b ≤ 0.3; 0.9 ≤ c ≤ 1.3; and 1.3 μm ≤ m ≤ 1.8 μm.

### CROSS-REFERENCE TO RELATED APPLICATION

This application claims the priority benefit of China application serial no. 202510125208.4, filed on January 26, 2025. The entirety of the above-mentioned patent application is hereby incorporated by reference herein and made a part of this specification.

### BACKGROUND

### Technical Field

The present disclosure generally relates to the field of micro-LEDs, and more specifically relates to a microlens for a micro-LED. Furthermore, the present disclosure also relates to a micro-LED chip having such a microlens.

### Description of Related Art

Micro light-emitting diode (Micro-LED) is a new type LED structure obtained by thin-filming, miniaturizing, and arraying the original LED structure, which integrates the arrayed micro level micro-LEDs on an active addressing drive panel to achieve the lighting and individual control of the micro-LEDs, thereby outputting the desired display image. The core structure of the micro-LED is a PN junction diode, which is composed of direct-bandgap semiconductor material. When the upper and lower electrodes apply a forward bias voltage to the micro-LED to allow current to pass through, electrons and holes recombine in the active area, and meanwhile emit monochromatic light photons.

Light extraction efficiency (LEE) refers to the proportion of photons generated inside the micro-LED that can be effectively emitted from the device to the outside. In the micro-LED, due to the characteristics of semiconductor materials and structures, some light will be absorbed, reflected, etc. inside and cannot be emitted, the improvement of light extraction efficiency can enhance the luminous performance of the device.

An effective measure to improve light extraction efficiency is to equip the micro-LED chip with a microlens. This is because the microlens can change the emergence angle of light in the micro-LED. Without a microlens, light may undergo total reflection at the positions such as the interface of the micro-LED chip with the package material, etc., resulting in light being confined inside the chip. Microlens can refract light and change the angle of the originally total reflected light, allowing it to exit the device. Furthermore, the microlens can also serve for focusing light. It can converge the light emitted by the micro-LED, such that the light is more concentrated and emitted outward.

A critical parameter of a microlens is the morphology of the microlens, which refers to the geometric shape and surface features of the microlens. It largely determines the optical behavior of the microlens, such as refraction, reflection, and focusing of light, etc. The morphology of the microlens will directly affect the shaping effect of the microlens on light, thereby affecting the light extraction efficiency.

Currently, there is still space for further optimization of the morphology of the microlens.

### SUMMARY

The task of the present disclosure aims to provide a microlens for a micro-LED and a micro-LED chip, and through the microlens and the micro-LED chip, the morphology of the microlens can be optimized, so that light extraction efficiency is improved.

In a first aspect of the present disclosure, the aforementioned task is achieved by a microlens for a micro-LED, the microlens includes: a lens portion, and a spacer portion arranged between a light-emitting mesa of the micro-LED and the lens portion, where the lens portion is arranged on the spacer portion.

In one embodiment of the present disclosure, the microlens further includes:

a connection portion arranged between adjacent microlenses and optically connecting the adjacent microlenses.

In another embodiment of the present disclosure, the surface of the connection portion facing the light extraction side is curved towards the light extraction side.

In another embodiment of the present disclosure, the connection portion is located at 30% to 100% of the height of the spacer portion.

In another embodiment of the present disclosure, the highest point of the connection portion is higher than the top of the spacer portion.

In another embodiment of the present disclosure, the connection portion is arranged on a reflective electrode, where the reflective electrode is arranged around the light-emitting mesa and configured to reflect light from the light-emitting mesa upward.

In another embodiment of the present disclosure, the diameter of the upper surface of the light-emitting mesa facing the microlens is n, the spherical height of the lens portion is a x n, the radius of curvature is m, the height of the spacer portion is b x n, the width of the spacer portion is c x n, and the radius of curvature of the lens portion is m, wherein a, b, c, m, and n are all positive numbers, where:

1.2 ≤ a ≤ 1.6;

0.2 ≤ b ≤ 0.3;

0.9 ≤ c ≤ 1.3; and

1.3 μm ≤ m ≤ 1.8 μm.

In another embodiment of the present disclosure, the central longitudinal cross-section of the lens portion is a part of an ellipse, where:

1.40 ≤ a ≤ 1.45;

0.25 ≤ b ≤ 0.30;

1.05 ≤ c ≤ 1.10; and

1.50 μm ≤ m ≤ 1.55 μm.

In another embodiment of the present disclosure, the major axis or minor axis of the ellipse is located within the top plane of the spacer portion.

In another embodiment of the present disclosure, the major axis or minor axis of the ellipse is parallel to the top plane of the spacer portion, and the major axis or minor axis of the ellipse is lower or higher than the top plane of the spacer portion.

In another embodiment of the present disclosure, the central longitudinal cross-section of the lens portion is a part of a circle, and:

1.20 ≤ a ≤ 1.30;

0.20 ≤ b ≤ 0.25;

1.22 ≤ c ≤ 1.30; and

1.70 μm ≤ m ≤ 1.75 μm.

In another embodiment of the present disclosure, the hemispherical bottom line of the circle is located within the top plane of the spacer portion.

In another embodiment of the present disclosure, the hemispherical bottom line of the circle is higher or lower than the top plane of the spacer portion.

In another embodiment of the present disclosure, the central longitudinal cross-section of the lens portion perpendicular to the upper surface is a part of a triangle, and:

1.55 ≤ a ≤ 1.60;

0.22 ≤ b ≤ 0.28;

0.90 ≤ c ≤ 1.10; and

1.33 μm ≤ m ≤ 1.40 μm.

In another embodiment of the present disclosure, the apex angle of the triangle is rounded.

In another embodiment of the present disclosure, the radius of the rounded arc is 0.2 to 0.5 μm.

In another embodiment of the present disclosure, 1.4 μm ≤ n ≤ 1.8 μm.

In a second aspect of the present disclosure, the aforementioned task is solved by a micro-LED chip, the micro-LED chip includes:

at least one light-emitting mesa configured to emit light; and

at least one microlens according to the present disclosure, which is arranged on the at least one light-emitting mesa.

In one embodiment of the present disclosure, the light-emitting mesa includes:

a transparent conductive layer arranged on a side of the light-emitting mesa facing away from the light extraction side;

a first epitaxial layer arranged between the transparent conductive layer and a light-emitting layer;

a light-emitting layer arranged between the first epitaxial layer and a second epitaxial layer and configured to emit light; and

a second epitaxial layer arranged on a side of the light-emitting mesa facing the light extraction side, where the area of the second epitaxial layer is greater than the area of the first epitaxial layer

In another embodiment of the present disclosure, the micro-LED chip further includes:

a reflective mirror layer configured to cover the side surface and bottom of the light-emitting mesa;

an insulating layer configured to accommodate the light-emitting mesa and the through-hole contact portions;

at least one drive circuit including a metal layer, the at least one drive circuit is provided with a plurality of through-hole contact portions, and the through-hole contact portions are electrically connected with the metal layer, and a micro-LED array area is bonded onto the at least one drive circuit through a bottom conductive bonding layer, where the at least one drive circuit further includes a wiring stacked layer below the metal layer, the wiring stacked layer is configured to lead out a first electrode;

the first electrode electrically connected with the through-hole contact portions;

a passivation layer covering at least a part of the side surface of the light-emitting mesa;

a top transparent conductive layer arranged on the surface of the passivation layer and in electrical contact with the second epitaxial layer; and

a second electrode arranged on the surface of the top transparent conductive layer.

In another embodiment of the present disclosure, the second electrode is a circular reflective electrode arranged around the light-emitting mesa.

In another embodiment of the present disclosure, the polarity of the second electrode is opposite to the polarity of the first electrode.

In another embodiment of the present disclosure, the material of the second epitaxial layer is a material layer of a second conductivity type including two or more elements of Ga, N, As, Al, In, and P, and the first epitaxial layer is a material layer of a first conductivity type including two or more elements of Ga, N, As, Al, In, and P, where the first conductivity type is different from the second conductivity type.

In another embodiment of the present disclosure, the light-emitting layer includes a multi-quantum-well layer, where the multi-quantum-well layer is an InGaN/GaN multi-quantum-well layer, an InGaN/AlGaN multi-quantum-well layer, an InGaAs/AlGaAs multi-quantum-well layer, or an AlGaInP multi-quantum-well layer.

In another embodiment of the present disclosure, a first side of the light-emitting layer is provided with an electron blocking layer, and the first side is a side along which electrons migrate out of the light-emitting layer.

In another embodiment of the present disclosure, the material of the passivation layer is a Si₃N₄ film, a SiO₂ film, or an Al₂O₃ film.

In another embodiment of the present disclosure, it is provided that:

the insulating layer is made of a material selected from a group consisting of silicon dioxide (SiO₂), aluminum oxide (Al₂O₃), silicon nitride (Si₃N₄), silicon carbide nitride (SiCN), hafnium oxide (HfO₂), tantalum pentoxide (Ta₂O₅), titanium dioxide (TiO₂), zirconium oxide (ZrO₂), lanthanum oxide (La₂O₃), magnesium oxide (MgO), phosphosilicate glass (PSG), boron phosphosilicate glass (BPSG), or any combination thereof; and/or

the metal layer is made of a material selected from a group consisting of aluminum (Al), copper (Cu), tungsten (W), silver (Ag), gold (Au), nickel (Ni), platinum (Pt), tantalum (Ta), and molybdenum (Mo).

In another embodiment of the present disclosure, the through-hole contact portions include a first and a second through-hole contact portions, and the insulating layers include a first and a second insulating layers, and the micro-LED chip includes an upper stacked layer and a lower stacked layer, where the upper stacked layer includes the first insulating layer, the light-emitting mesa, and the first through-hole contact portion, and the lower stacked layer includes the second insulating layer, the second through-hole contact portion, and the drive circuit, where the lower stacked layer is jointed with the upper stacked layer through hybrid bonding, such that the first through-hole contact portion is bonded with the second through-hole contact portion, and the first insulating layer is bonded with the second insulating layer.

In another embodiment of the present disclosure, the reflective mirror layer includes an atomic layer deposition layer on a side of the reflective mirror layer facing the light-emitting mesa, and the atomic layer deposition layer is configured to block metal diffusion in the reflective mirror layer.

In another embodiment of the present disclosure, the reflective mirror layer includes, starting from the side facing the light-emitting mesa:

an atomic layer deposition layer, made of a material selected from a group consisting of nickel, platinum, titanium, and tantalum;

a reflective metal layer configured to reflect light, the reflective metal layer is made of a material selected from a group consisting of silver, aluminum, and gold;

a first barrier layer including at least a first and a second barrier sublayers, where the first barrier sublayer and the second barrier sublayer are made of a material selected from a group consisting of platinum, titanium, and tantalum; and

the second barrier layer, made of a material selected from a group consisting of platinum, titanium, and tantalum.

In another embodiment of the present disclosure, the second epitaxial layer includes:

a step portion in electrical contact with the light-emitting layer; and

a base portion extending from the step portion to two sides.

In another embodiment of the present disclosure, the base portions of adjacent light-emitting mesas are connected with each other.

In another embodiment of the present disclosure, it is provided that:

the thickness of the step portion is: 400 nm to 800 nm; and/or

the thickness of the base portion is 4 to 4.4 μm.

In another embodiment of the present disclosure, it is provided that:

the thickness of the transparent conductive layer is: 80 to 150 nm; and/or

the thickness of the first epitaxial layer is: 250 to 350 nm; and/or

the thickness of the light-emitting layer is: 200 to 400 nm; and/or

the thickness of the second epitaxial layer is: 180 to 450 nm.

The present disclosure has at least the following beneficial effects:

(1) Through research, the inventors discovered that when the ratio a between the spherical height an of the lens portion and the diameter n of the upper surface of the light-emitting mesa facing the microlens, the ratio b between the height of the spacer portion and the diameter, the ratio c between the width of the spacer portion and the diameter, and the curvature radius m of the lens portion are within a certain range of values, the light extraction efficiency of the micro-LED can be significantly improved, where the range of values is as follows:

1.2 ≤ a ≤ 1.6;

0.2 ≤ b ≤ 0.3;

0.9 ≤ c ≤ 1.3; and

1.3 ≤ m ≤ 1.8.

The principle of optimizing light extraction efficiency by the aforementioned range of values is that when the aforementioned parameters of the lens portion of the microlens are within the aforementioned range of values, the morphology of the microlens is optimized, so that more light can be output from the microlens, meanwhile, less light is absorbed by the components inside the micro-LED and less light enters adjacent micro-LEDs.

(2) Meanwhile, in the aforementioned larger range of values, there are also three smaller ranges of values that are more optimal:

A. The central longitudinal cross-section of the lens portion is a part of an ellipse, and the range of values is the following numerical intervals:

1.40 ≤ a ≤ 1.45;

0.25 ≤ b ≤ 0.30;

1.05 ≤ c ≤ 1.10; and

1.50 ≤ m ≤ 1.55.

B. The central longitudinal cross-section of the lens portion is a part of a circle, and the range of values is the following numerical intervals:

1.20 ≤ a ≤ 1.30;

0.20 ≤ b ≤ 0.25;

1.22 ≤ c ≤ 1.30; and

1.70 ≤ m ≤ 1.75.

C. The central longitudinal cross-section of the lens portion is a part of a triangle, and the range of values is the following numerical intervals:

1.55 ≤ a ≤ 1.60;

0.22 ≤ b ≤ 0.28;

0.90 ≤ c ≤ 1.10; and

1.33 ≤ m ≤ 1.40.

By the aforementioned morphology of the lens portion and a more optimal range of values, the light extraction efficiency of the micro-LED can be further improved.

(3) By adding an atomic layer deposition layer made of a barrier metal on the side of the reflective mirror layer facing the light-emitting mesa, it is possible to effectively prevent performance degradation or failure of the light-emitting mesa caused by the metal in the reflective mirror layer diffusing into the light-emitting mesa through the bottom transparent conductive layer arranged between the reflective mirror layer and the light-emitting mesa, and oxidation of the reflective metal is suppressed, and thus the reduction in reflection efficiency caused by oxidation is suppressed.

### BRIEF DESCRIPTION OF THE DRAWINGS

The present disclosure is further explained below with reference to the accompanying drawings in conjunction with specific implementation methods.

FIGS. 1A and 1B illustrate a first embodiment of the microlens according to the present disclosure.

FIG. 2 illustrates a second embodiment of the microlens according to the present disclosure.

FIGS. 3A and 3B illustrate a third embodiment of the microlens according to the present disclosure.

FIG. 4 illustrates a fourth embodiment of the microlens according to the present disclosure.

FIGS. 5A and 5B illustrate a fifth embodiment of the microlens according to the present disclosure.

FIG. 6 illustrates a sixth embodiment of the microlens according to the present disclosure.

FIG. 7 illustrates a schematic diagram of a micro-LED chip having the microlens according to the present disclosure.

FIG. 8 illustrates a top view schematic diagram of the micro-LED chip according to the present disclosure.

### DESCRIPTION OF THE EMBODIMENTS

It should be noted that various components in the accompanying drawings may be exaggerated for the purpose of illustrative illustration and are not necessarily true to scale. In the accompanying drawings, components that are identical or functionally identical are provided with the same accompanying drawing reference signs.

In the present disclosure, unless otherwise specified, the words "arranged on", "arranged above" and "arranged over" do not exclude the existence of intermediates between the two. Furthermore, "arranged on or above" merely indicates the relative positional relationship between the two components, but under certain circumstances, such as when the product direction is reversed, it can be converted to "arranged under or below", and vice versa.

In the present disclosure, the embodiments are merely intended to illustrate the scheme of the present disclosure and should not be construed as limiting.

In the present disclosure, the quantifiers "a" and "one" do not exclude scenarios with a plurality of elements, unless otherwise specified.

In the present disclosure, the term "connect" may refer to either the two being directly connected or the two being indirectly connected through an intermediate component.

In the present disclosure, the term "configure" refers to the setting of the shape, structure, material, and/or function of a target object to achieve a desired technical effect, where "configure" includes various alternative technical means to achieve this technical effect, and these technical means become apparent under the teachings of the present disclosure.

It should also be noted herein that in embodiments of the present disclosure, merely a part of the components or assemblies may be shown for the sake of clarity and simplicity, but those ordinary skilled in the art will be able to understand that the required components or assemblies may be added as needed according to specific scenarios in light of the teachings of the present disclosure. Furthermore, features in different embodiments of the present disclosure may be combined with each other unless otherwise indicated. For example, a feature in the second embodiment may be substituted for a corresponding or functionally identical or similar feature in the first embodiment, and the obtained embodiment likewise falls within the scope of the disclosure or the scope of the record of the present application.

It should also be noted that, within the scope of the present disclosure, the terms "the same", "equal", "equal to", etc. do not mean that the two numerical values are absolutely equal, but rather allow for a certain reasonable error, that is to say, the terms also cover "substantially the same ", "substantially equal " and "substantially equal to". By analogy, in the present disclosure, the terms "perpendicular to", "parallel to", etc., which indicate direction, also cover the meaning of "substantially perpendicular to", "substantially parallel to".

In the present disclosure, the term "configure" refers to the setting of the shape, structure, material, and/or function of a target object to achieve a desired technical effect, where "configure" includes various alternative technical means to achieve this technical effect, and these technical means become apparent under the teachings of the present disclosure.

In the present disclosure, the term "spacing between adjacent light-emitting mesas" refers to the edge distance between adjacent light-emitting mesas in a central longitudinal cross-section perpendicular to the bottom surface of the light-emitting mesa.

In the present disclosure, the term "light extraction side of the light-emitting mesa" refers to the side from which light is outputted by the light-emitting mesa, i.e., the side from which light generated by the light-emitting mesa leaves the light-emitting mesa to output outward. For example, the light extraction side of the light-emitting mesa is the side where the microlens is located. Similarly, the term "a side of the light-emitting mesa facing away from the light extraction side" refers to the side of the light-emitting mesa opposite to the light extraction side, such as the side facing the drive circuit or the drive backplane.

In the present disclosure, the term "central cross-section of the microlens" refers to the cross-section passing through the optical axis of the microlens. The term "longitudinal cross-section of the microlens" refers to the cross-section of the microlens made in a direction perpendicular to the upper surface of the light-emitting mesa facing the light extraction side, while the term "cross-section of the microlens" refers to the cross-section of the microlens made in a direction parallel to the upper surface of the light-emitting mesa facing the light extraction side. Therefore, the term "central longitudinal cross-section of the microlens" refers to the longitudinal cross-section of the microlens passing through its optical axis.

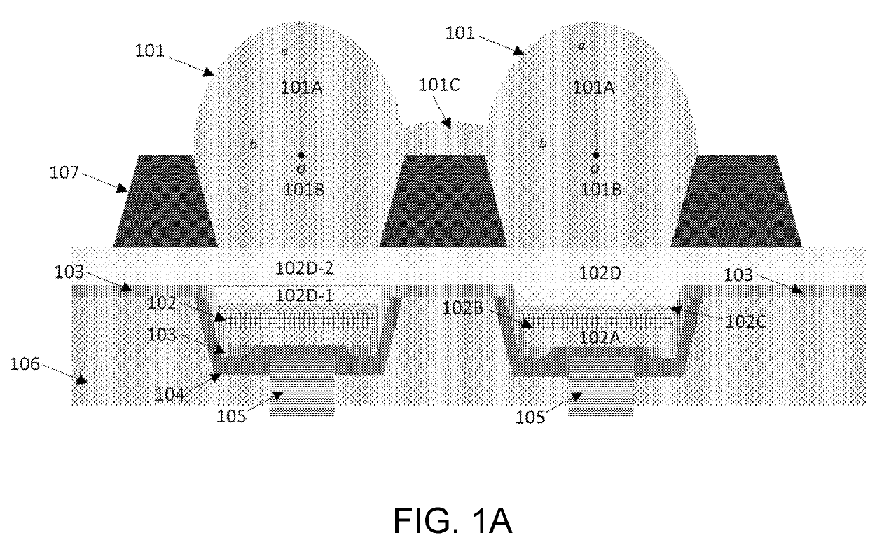

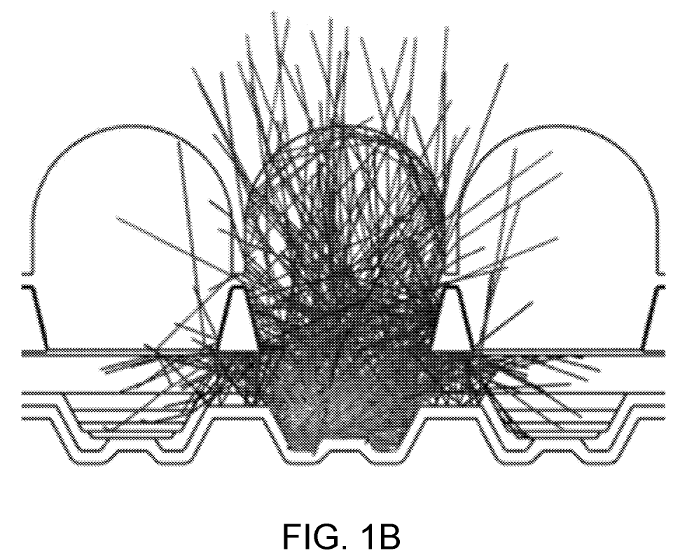

FIGS. 1A and 1B illustrate a first embodiment of the microlens according to the present disclosure, where FIG. 1A illustrates a schematic diagram of the microlens having an elliptical central longitudinal cross-section, and FIG. 1B illustrates a schematic diagram of its light extraction simulation.

As shown in FIG. 1A, the microlens 101 according to the present disclosure includes a lens portion 101A, a spacer portion 101B, and a connection portion 101C. The boundary between the lens portion 101A and the spacer portion 101B is indicated by the dashed line in the figure. The spacer portion 101B is arranged between the light-emitting mesa 102 of the micro-LED and the lens portion 101A to adjust the position of the focal point of the lens portion 101A relative to the light-emitting mesa 102. The lens portion 101A is arranged on the spacer portion 101B to shape light emitted from the light-emitting mesa 102. The connection portion 101C is arranged on the reflective electrode 107, where the reflective electrode 107 is arranged around the light-emitting mesa 102 and configured to reflect light from the light-emitting mesa 102 toward the microlens 101.

In the present embodiment, the central longitudinal cross-section of the lens portion 101A is a part of an ellipse, herein is a semi-ellipse. Herein, the term "central longitudinal cross-section" refers to the section made on the lens portion 101A through the optical axis of the lens portion and perpendicular to the light-emitting mesa 102. The center of the ellipse of the lens portion is o, the semi-major axis is a, and the semi-minor axis is b. In the present embodiment, the semi-minor axis b of the ellipse coincides precisely with the boundary of the spacer portion 101B, and the center o of the ellipse also lies on the boundary of the spacer portion 101B, i.e., on the upper surface. In other embodiments, the semi-minor axis of the ellipse may be higher or lower than the upper surface of the spacer portion 101B, or the semi-major axis a of the ellipse may lie on the boundary of the spacer portion 101B. In the present embodiment, the lower surface of the connection portion 101C is arranged on the reflective electrode 107 and has the same shape as the upper surface of the reflective electrode 107, and the connection portion 101C has an arcuate upper surface, and this arc curves toward the direction of the microlens, and its curvature may be, for example, 0.2 to 0.4. In other embodiments, the connection portion 101C may have other shapes, for example, a flat shape or a triangle, etc. The connection portion 101C optically connects adjacent microlenses with each other. The protruding upper surface of the connection portion 101C can reflect light from the microlens upward, thereby preventing it from entering the adjacent microlens and thus preventing optical crosstalk between adjacent micro-LEDs.

In the present embodiment, the parameters of the microlens 101 are as follows:

The diameter of the upper surface of the light-emitting mesa 102 facing the microlens 101 is n;

The spherical height of the lens portion is a x n (a multiplied by n, the same below);

The curvature radius is m;

The height of the spacer portion is b x n;

The width of the spacer portion is c x n;

The curvature radius of the lens portion is d x m;

where a, b, c, m, and n are all positive numbers, and a, b, c, m, and n have the following range of values:

1.40 ≤ a ≤ 1.45, where the most preferred value for a is 1.43;

0.25 ≤ b ≤ 0.30, where the most preferred value for b is 0.28;

1.05 ≤ c ≤ 1.10, where the most preferred value for c is 1.10;

1.50 ≤ m ≤ 1.55, where the most preferred value for m is 1.54 μm;

1.4 μm ≤ n ≤ 1.8 μm, where the most preferred value for n is 1.6 μm.

The light-emitting mesa 102 is described below.

The light-emitting mesa 102 is arranged in a recess in the insulating layer 106 and configured to emit light. The light-emitting mesa 102 sequentially includes, from the side of the microlens 101: a bottom transparent conductive layer 102A, a first epitaxial layer 102B, a light-emitting layer 102C, and a second epitaxial layer 102D. The second epitaxial layer 102D includes a step portion 102D-1 and an extension portion 102D-2. The step portion 102D-1 is in contact with the light-emitting layer 102C, while the extension portion 102D-2 extends from the step portion 102D-1 toward two sides of the light-emitting mesa 102, and the extension portions 102D-2 of adjacent light-emitting mesas 102 are connected with each other as a whole. In this way, the area and thickness of the second epitaxial layer 102D can be significantly increased, which is beneficial for improving light output. The thickness of the step portion may be, for example, 400 nm to 800 nm, and the thickness of the base portion may be, for example, 4 μm to 4.4 μm. Furthermore, the thickness of the transparent conductive layer may be, for example, 80 to 150 nm; the thickness of the first epitaxial layer 102B may be, for example, 250 to 350 nm; the thickness of the light-emitting layer may be, for example, 200 to 400 nm; and the thickness of the second epitaxial layer may be, for example, 180 to 450 nm. A passivation layer 103 is arranged on the side surface and a part of the bottom of the light-emitting mesa 102. Furthermore, the passivation layer 103 also extends from the light-emitting mesa 102 toward its two sides. The passivation layer 103 has a notch at the bottom of the light-emitting mesa 102, so that the bottom transparent conductive layer 102A can be electrically connected to the through-hole contact portion 105 through the reflective mirror layer 104. The reflective mirror layer 104 is arranged around at least a part of the side surface and the bottom of the light-emitting mesa 102, where the reflective mirror layer 104 is configured to reflect light from the light-emitting mesa 102 toward the microlens 101. The reflective mirror layer 104 is electrically connected with the through-hole contact portion 105 to electrically connect the first epitaxial layer 102B of the light-emitting mesa 102 to an electrode, such as an anode.

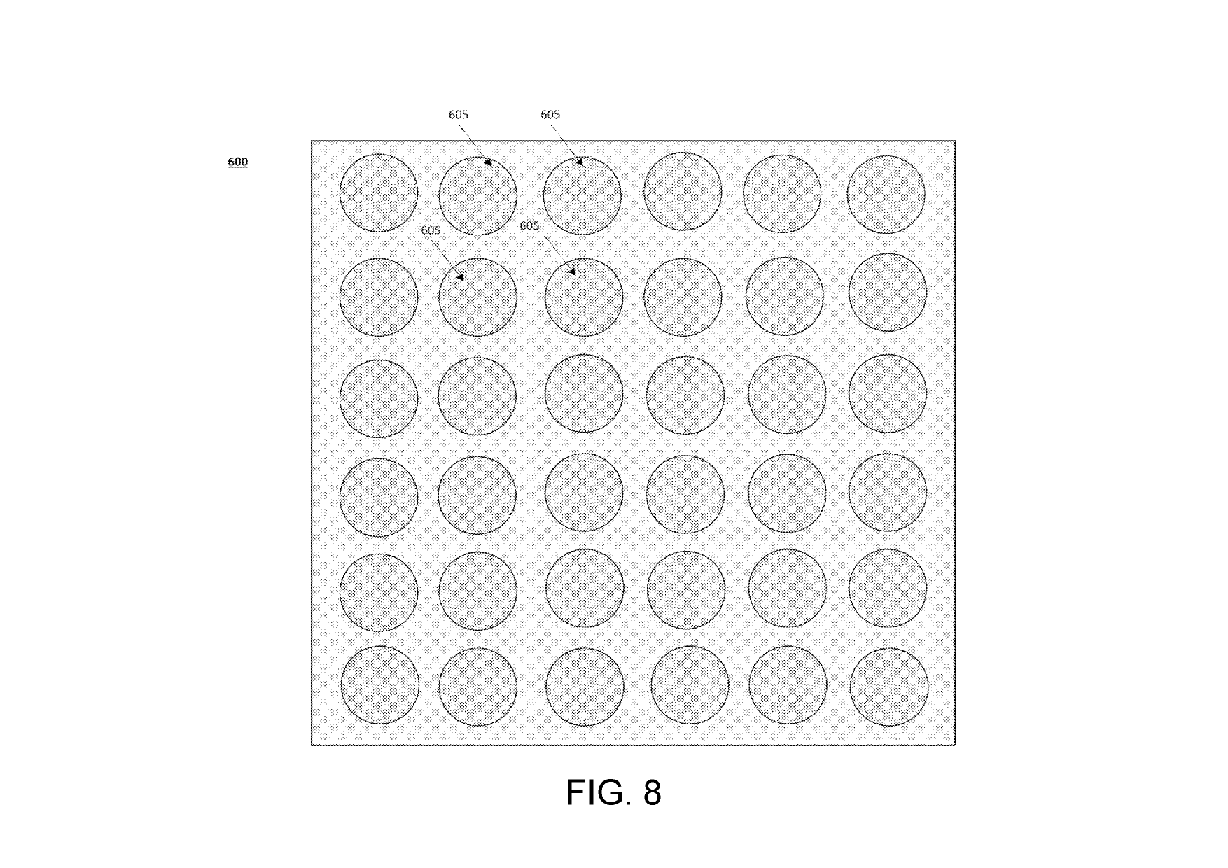

For a more detailed description of the light-emitting mesa 102, reference may be made to FIG. 8 and its description.

FIG. 1B illustrates a schematic diagram of the light extraction of the microlens in FIG. 1A.

As shown in FIG. 1B, in the case of using the microlens shown in FIG. 1A according to the present disclosure, the vast majority of light emitted from the light-emitting mesa is output from the microlens, meanwhile, light entering the adjacent micro-LEDs from the second epitaxial layer and the connection portion between the microlenses of adjacent micro-LEDs is significantly reduced, so that light extraction efficiency is significantly improved and optical crosstalk is reduced.

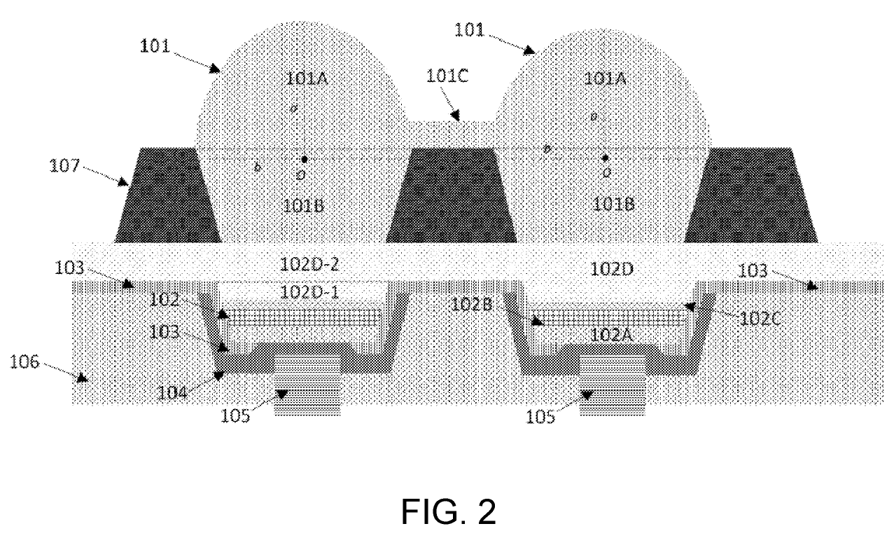

FIG. 2 illustrates a second embodiment of the microlens according to the present disclosure.

The second embodiment shown in FIG. 2 is substantially the same as the first embodiment shown in FIG. 1A, and the primary difference lies in that, in the second embodiment, the semi-minor axis b of the ellipse of the central longitudinal cross-section of the lens portion 101A is not located within the top plane of the spacer portion 101B, and on the contrary, the semi-minor axis b of the ellipse is parallel to the top plane of the spacer portion 101B and lower than the top plane of the spacer portion 101B; furthermore, the upper surface of the connection portion between adjacent microlenses 101 is flat. In other embodiments, the semi-major axis b of the ellipse can also be made parallel to the top plane of the spacer portion 101B and lower than the top plane of the spacer portion 101B.

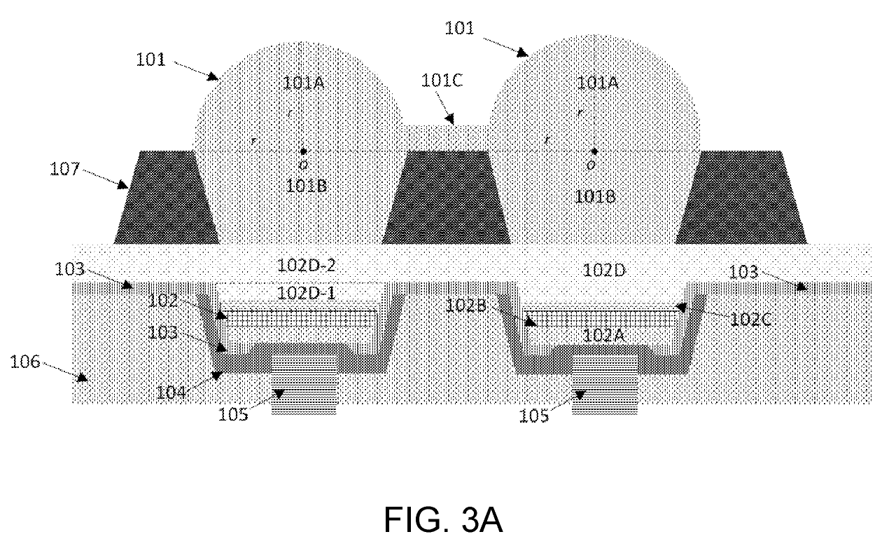

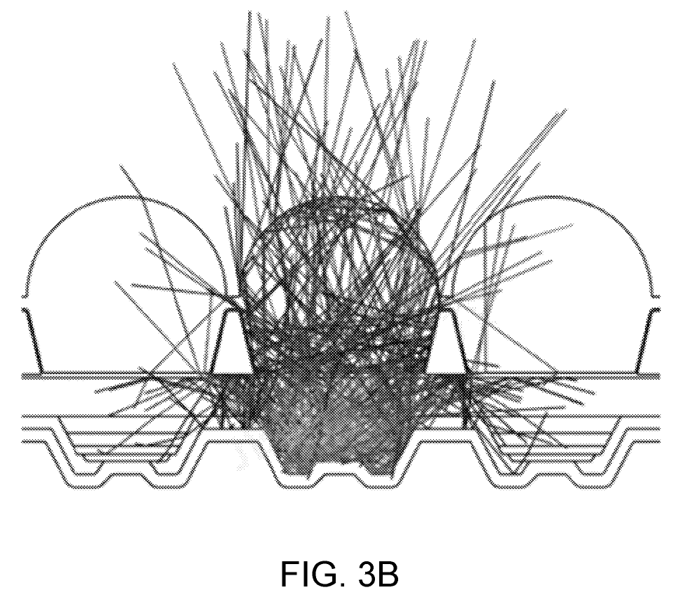

FIGS. 3A and 3B illustrate a third embodiment of the microlens according to the present disclosure, where FIG. 3A illustrates a schematic diagram of the microlens having a circular central longitudinal cross-section, and FIG. 3B illustrates a schematic diagram of its light extraction simulation.

As shown in FIG. 3A, the microlens 101 according to the present disclosure includes a lens portion 101A, a spacer portion 101B, and a connection portion 101C. The boundary between the lens portion 101A and the spacer portion 101B is indicated by the dashed line in the figure. The spacer portion 101B is arranged between the light-emitting mesa 102 of the micro-LED and the lens portion 101A to adjust the position of the focal point of the lens portion 101A relative to the light-emitting mesa 102. The lens portion 101A is arranged on the spacer portion 101B to shape light emitted from the light-emitting mesa 102. The connection portion 101C is arranged on the reflective electrode 107, where the reflective electrode 107 is arranged around the light-emitting mesa 102 and configured to reflect light from the light-emitting mesa 102 toward the microlens 101.

In the present embodiment, the central longitudinal cross-section of the lens portion 101A is a part of a circle, herein is a semicircle. Herein, the term "central longitudinal cross-section" refers to the section made on the lens portion 101A through the optical axis of the lens portion and perpendicular to the light-emitting mesa 102. The center of the circle of the lens portion 101A is o, and the radius is r. In the present embodiment, the radius r of the circle coincides precisely with the boundary of the spacer portion 101B, and the center o also lies on the boundary of the spacer portion 101B, i.e., on the upper surface. In other embodiments, the radius r of the circle may be higher or lower than the upper surface of the spacer portion 101B. In the present embodiment, the lower surface of the connection portion 101C is arranged on the reflective electrode 107 and has the same shape as the upper surface of the reflective electrode 107, and the connection portion 101C has a flat upper surface, with a thickness that may be, for example, 0.2 μm to 0.5 μm. In other embodiments, the connection portion 101C may have other shapes, such as an arcuate shape or a triangle, etc. The connection portion 101C optically connects adjacent microlenses with each other.

In the present embodiment, the parameters of the microlens 101 are as follows:

The diameter of the upper surface of the light-emitting mesa 102 facing the microlens 101 is n;

The spherical height of the lens portion is calculated as a x n (a multiplied by n, the same below);

The curvature radius is m;

The height of the spacer portion is calculated as b x n;

The width of the spacer portion is calculated as c x n;

The curvature radius of the lens portion is calculated as d x m;

where a, b, c, m, and n are all positive numbers, and a, b, c, m, and n have the following range of values:

1.20 ≤ a ≤ 1.30, where the most preferred value for a is 1.25;

0.20 ≤ b ≤ 0.25, where the most preferred value for b is 0.23;

1.22 ≤ c ≤ 1.30, where the most preferred value for c is 1.27;

1.70 μm ≤ m ≤ 1.75 μm, where the most preferred value for m is 1.73 μm;

1.4 μm ≤ n ≤ 1.8 μm, where the most preferred value for n is 1.6 μm.

FIG. 3B illustrates a schematic diagram of the light extraction of the microlens in FIG. 3A.

As shown in FIG. 3B, in the case of using the microlens shown in FIG. 3A according to the present disclosure, the vast majority of light emitted from the light-emitting mesa is output from the microlens, meanwhile, light entering the adjacent micro-LEDs from the second epitaxial layer and the connection portion between the microlenses of adjacent micro-LEDs is significantly reduced, so that light extraction efficiency is significantly improved and optical crosstalk is reduced.

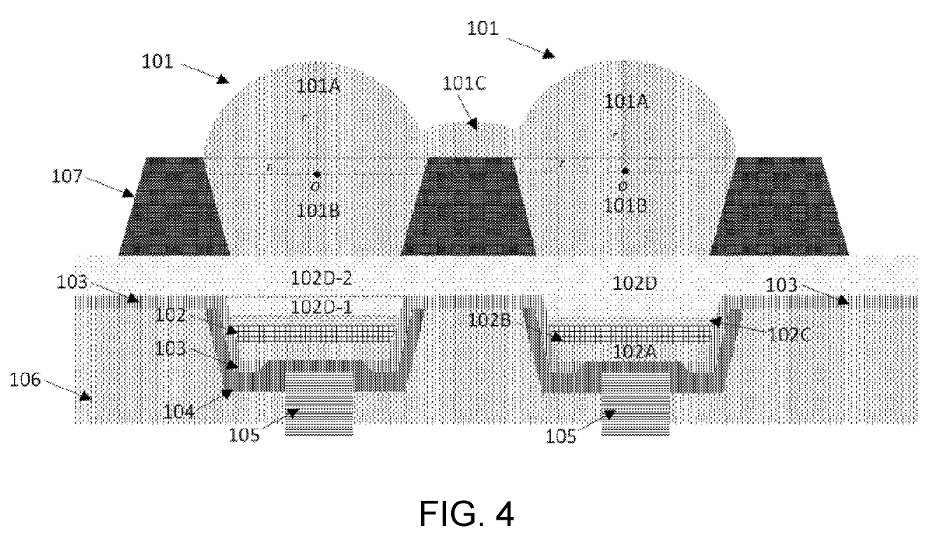

FIG. 4 illustrates a fourth embodiment of the microlens according to the present disclosure.

The fourth embodiment shown in FIG. 4 is substantially the same as the third embodiment shown in FIG. 3A, and the primary difference lies in that, in the fourth embodiment, the radius r of the circle of the central cross-section of the lens portion 101A is not located within the top plane of the spacer portion 101B, and on the contrary, the radius r of the circle is parallel to the top plane of the spacer portion 101B and lower than the top plane of the spacer portion 101B; furthermore, the upper surface of the connection portion between adjacent microlenses 101 is an arc, and the arc is curved toward the direction of the microlens and its curvature may be, for example, 0.6 to 0.8.

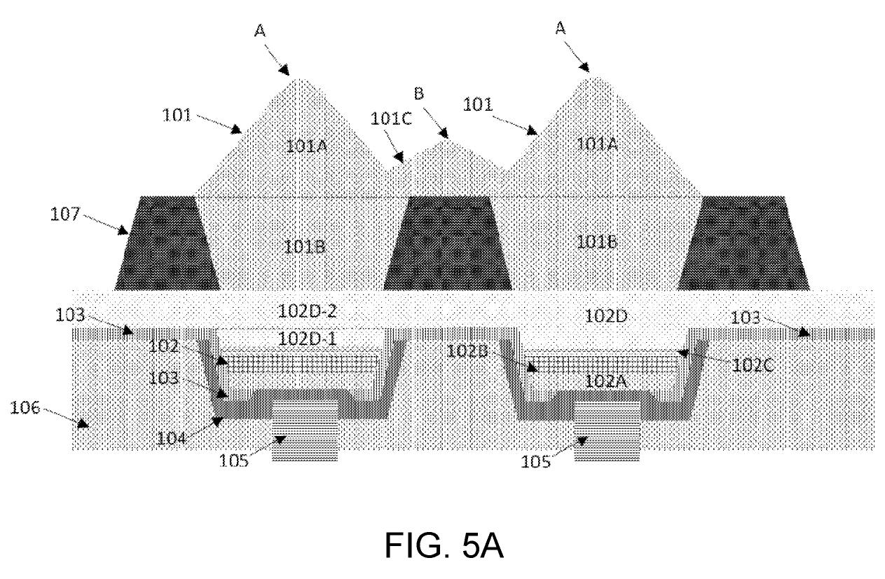

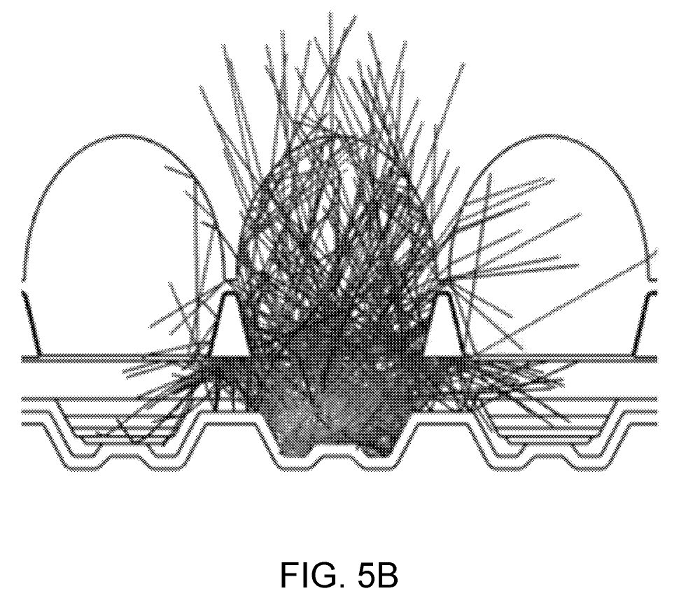

FIGS. 5A and 5B illustrate a fifth embodiment of the microlens according to the present disclosure, wherein FIG. 5A illustrates a schematic diagram of the microlens having a triangular central longitudinal cross-section, and FIG. 5B illustrates a schematic diagram of its light extraction simulation.

As shown in FIG. 5A, the microlens 101 according to the present disclosure includes a lens portion 101A, a spacer portion 101B, and a connection portion 101C. The boundary between the lens portion 101A and the spacer portion 101B is indicated by the dashed line in the figure. The spacer portion 101B is arranged between the light-emitting mesa 102 of the micro-LED and the lens portion 101A to adjust the position of the focal point of the lens portion 101A relative to the light-emitting mesa 102. The lens portion 101A is arranged on the spacer portion 101B to shape light emitted from the light-emitting mesa 102. The connection portion 101C is arranged on the reflective electrode 107, wherein the reflective electrode 107 is arranged around the light-emitting mesa 102 and configured to reflect light from the light-emitting mesa 102 toward the microlens 101.

In the present embodiment, the central longitudinal cross-section of the lens portion 101A is a part of a triangle, herein is a triangle with a rounded apex angle A. Herein, the term "central longitudinal cross-section" refers to the section made on the lens portion 101A through the optical axis of the lens portion and perpendicular to the light-emitting mesa 102. In the present embodiment, the triangle of the central longitudinal cross-section is an acute-angled triangle, and the arc radius of the rounded apex angle A is 0.2 to 0.5 μm. In other embodiments, the triangle of the central longitudinal cross-section may also be an obtuse-angled triangle. In the present embodiment, the base of the triangle coincides with the boundary of the spacer portion 101B. In the present embodiment, the lower surface of the connection portion 101C is arranged on the reflective electrode 107 and has the same shape as the upper surface of the reflective electrode 107, and the connection portion 101C has a triangular upper surface, and the triangle has a rounded apex angle B, and the arc radius of the rounded apex angle B is 0.2 to 0.5 μm. The connection portion 101C optically connects adjacent microlenses with each other. The protruding upper surface of the connection portion 101C can reflect light from the microlens upward, thereby preventing it from entering the adjacent microlens and thus preventing optical crosstalk between adjacent micro-LEDs.

In the present embodiment, the parameters of the microlens 101 are as follows:

The diameter of the upper surface of the light-emitting mesa 102 facing the microlens 101 is n;

The spherical height of the lens portion is a x n (a multiplied by n, the same below);

The curvature radius is m;

The height of the spacer portion is b x n;

The width of the spacer portion is c x n;

The curvature radius of the lens portion is d x m;

wherein a, b, c, m, and n are all positive numbers, and a, b, c, m, and n have the following range of values:

1.55 ≤ a ≤ 1.60, wherein the most preferred value for a is 1.56;

0.22 ≤ b ≤ 0.28, wherein the most preferred value for b is 0.25;

0.90 ≤ c ≤ 1.10, wherein the most preferred value for c is 1.00

1.33 μm ≤ m ≤ 1.40 μm, wherein the most preferred value for m is 1.38 μm

1.4 μm ≤ n ≤ 1.8 μm, wherein the most preferred value for n is 1.6 μm.

FIG. 5B illustrates a simulation schematic diagram of the light extraction of the microlens in FIG. 5A.

As shown in FIG. 5B, in the case of using the microlens shown in FIG. 5A according to the present disclosure, the vast majority of light emitted from the light-emitting mesa is output from the microlens, meanwhile, light entering the adjacent micro-LEDs from the second epitaxial layer and the connection portion between the microlenses of adjacent micro-LEDs is significantly reduced, so that light extraction efficiency is significantly improved and optical crosstalk is reduced.

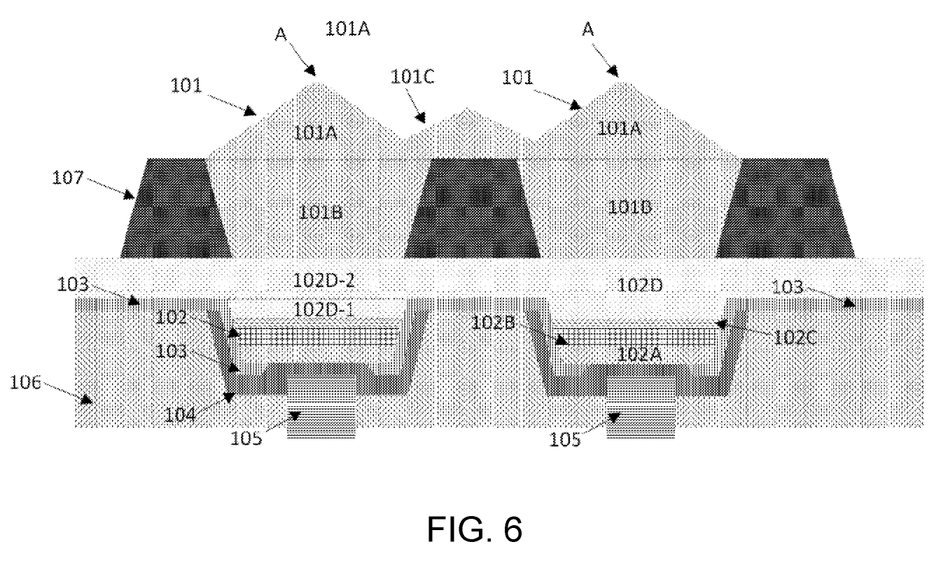

FIG. 6 illustrates a sixth embodiment of the microlens according to the present disclosure.

The sixth embodiment shown in FIG. 6 is substantially the same as the fifth embodiment shown in FIG. 5A, and the primary difference lies in that, in the sixth embodiment, the triangle of the central longitudinal cross-section of the lens portion 101A is an obtuse-angled triangle, i.e., its apex angle A is an obtuse angle. Furthermore, the apex angle A is rounded, wherein the arc radius of the rounded apex angle A is 0.2 to 0.5 μm. Furthermore, the upper surface of the connection portion between adjacent microlenses 101 is a triangle and does not have a rounded apex angle.

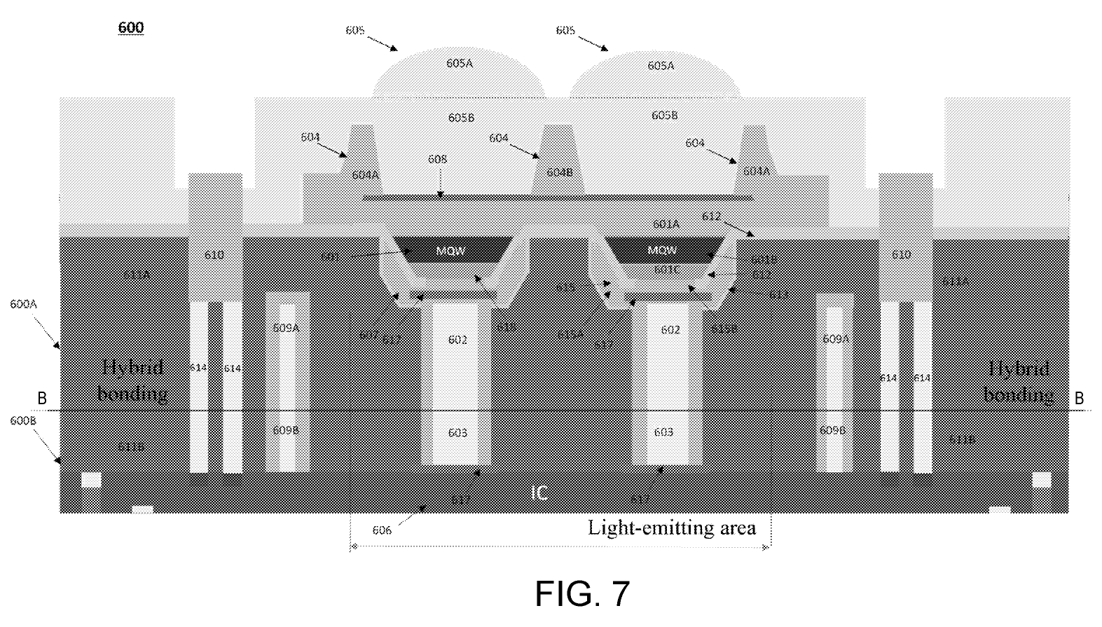

FIG. 7 illustrates a schematic diagram of a micro-LED chip 600 having the microlens according to the present disclosure.

In this application scenario, the light-emitting mesa or epitaxial layer of the micro-LED chip 600 has an upside-down arranged trapezoidal structure, i.e., its light-emitting mesa is a structure with a larger upper surface and a smaller lower surface, and the inclination angle of the light-emitting mesa is 55° to 75°, preferably 60° to 70°. The microlens of the micro-LED chip 600 has an elliptical, circular, or (rounded apex angle) triangular central longitudinal cross-section. In this embodiment, the microlens is shown to have a semi-elliptical central longitudinal cross-section.

The various components of the micro-LED chip 600 are described in detail below.

As shown in FIG. 7, the micro-LED chip 600 according to the present disclosure includes an upper stacked layer 600A and a lower stacked layer 600B, wherein the upper stacked layer 600A and the lower stacked layer 600B are formed into a complete micro-LED chip 600 through hybrid bonding at interface B. The structure and components of the upper stacked layer 600A and the lower stacked layer 600B are described in detail below.

### Upper stacked layer

The upper stacked layer 600A includes a first insulating layer 611A, a light-emitting mesa 601, a top transparent conductive layer 608, a first electrode 604 (cathode), a first through-hole contact portion 602, a second electrode 610 (anode), a first bonding mark 609A, and microlens 605. The various components are described below, respectively.

The first insulating layer 611A is configured to accommodate at least a part of the light-emitting mesa 601 and provide electrical insulation for the light-emitting mesa 601. Herein, the first insulating layer 611A has a recess 607 configured to accommodate the light-emitting layer and the second epitaxial layer of the light-emitting mesa 601, as well as ancillary structures of the light-emitting mesa 601. For a detailed description of the light-emitting mesa 601 and the ancillary structures (such as the passivation layer 612, the reflective mirror layer 615, etc.), reference may be made to the light-emitting mesa 601 and description thereof. Herein, it should be noted that the recess 607 may be formed after the light-emitting mesa 601, i.e., the light-emitting mesa 601 and the ancillary structures are first formed on a temporary substrate, then the first insulating layer 611A surrounding the light-emitting mesa 601 and the ancillary structures is formed on the light-emitting mesa and the ancillary structures. The material of the first insulating layer 611A may be, for example, silicon dioxide, silicon nitride, high-k dielectric materials (such as hafnium oxide, aluminum oxide, etc.), and so on. Methods for forming the first insulating layer 611A may include thermal oxidation, chemical vapor deposition (CVD), etc. The thickness of the first insulating layer 611A is, for example, 1 to 3 μm, preferably 2 μm, and more preferably 0.6 to 1.4 μm. Furthermore, the first insulating layer 611A may be planarized at interface B (e.g., through chemical mechanical polishing CMP) to facilitate hybrid bonding with the second insulating layer 611B.

The first insulating layer 611A is transparent to light emitted from the light-emitting mesa 601. In some embodiments, the first insulating layer 611A is made of a dielectric material such as solid inorganic material or plastic material. In some embodiments, the solid inorganic material includes silicon dioxide (SiO₂), aluminum oxide (Al₂O₃), silicon nitride (Si₃N₄), silicon carbide nitride (SiCN), hafnium oxide (HfO₂), tantalum pentoxide (Ta₂O₅), titanium dioxide (TiO₂), zirconium oxide (ZrO₂), lanthanum oxide (La₂O₃), magnesium oxide (MgO), phosphosilicate glass (PSG), boron phosphosilicate glass (BPSG), or any combination thereof. In some embodiments, the plastic material includes polymers such as SU-8, PermiNex, or benzocyclobutene (BCB), or transparent plastics (resins) including spin-on glass (SOG), or adhesive micro resist BCL-1200, or any combination thereof. In some embodiments, the first insulating layer 611A may facilitate the passage of light emitted from the light-emitting mesa 601. In some embodiments, the first insulating layer 611A may include a plurality of portions, such as three embedded dielectric portions and two adhering dielectric portions. The embedded dielectric portions refer to the dielectric layers surrounding each light emitting diode structure; while the adhering dielectric portions refer to the dielectric layers between two light emitting diode structures. The embedded dielectric portions and the adhering dielectric portions may have the same or different compositions.

The light-emitting mesa 601 is configured to emit light, wherein the top surface area of the light-emitting mesa 601 is greater than the bottom surface area of the light-emitting mesa 601, the light-emitting mesa 601 is in the shape of an upside-down arranged trapezoid. The inclination angle of light-emitting mesa 601 according to the present disclosure is 55° to 75°, preferably 60° to 70°. The light-emitting mesa 601 includes a first epitaxial layer 601A (corresponding to the second epitaxial layer 102D in FIG. 1A), a light-emitting layer 601B (corresponding to the light-emitting layer 102C in FIG. 1A), and a second epitaxial layer 601C (corresponding to the first epitaxial layer 102B in FIG. 1A), wherein the first epitaxial layer 601A is arranged on the top surface of the light-emitting mesa, i.e., the side facing the light extraction surface; the light-emitting layer 601B is arranged in the recess 607 and arranged between the first epitaxial layer 601A and the second epitaxial layer 601C; and the second epitaxial layer 601C is arranged on the bottom of the light-emitting mesa 601, i.e., the side facing the drive circuit 606. The light-emitting layer 601B may include, for example, a multi-quantum-well layer and an electron barrier layer. In one embodiment of the present disclosure, the first epitaxial layer 601A is an N-type GaN layer or an N-type AlGaN layer, and the second epitaxial layer 601C is a P-type GaN layer or a P-type AlGaN layer, i.e., the material of the second epitaxial layer 601C is a material layer of a second conductivity type including at least two or more elements of Ga, N, As, Al, In, and P, and the first epitaxial layer 601A is a material layer of a first conductivity type including at least two or more elements of Ga, N, As, Al, In, and P. The multi-quantum-well layer is an InGaN/GaN multi-quantum-well layer, an InGaN/AlGaN multi-quantum-well layer, or an InGaAs/AlGaAs multi-quantum-well layer. The electron barrier layer is arranged on the first side of the light-emitting layer, and the first side refers to the side along which electrons migrate out of the light-emitting layer. In yet another embodiment of the present disclosure, the first epitaxial layer 601A may also be a P-type GaN layer or a P-type AlGaN layer, and the second epitaxial layer 601C is an N-type GaN layer or an N-type AlGaN layer. The top width of the light-emitting mesa 601 is, for example, 0.5 to 3 μm, preferably 1.0 to 2.0 μm. The thickness of the first epitaxial layer 601A is, for example, 4000 to 5000 Å, the thickness of the light-emitting layer 601B is, for example, 3500 to 4000 Å, and the thickness of the second epitaxial layer 601C is, for example, 2500 to 3500 Å. 1 angstrom (Å) = 10^(-10) m. From FIG. 7, it can also be seen that the extension portion of the first epitaxial layer 601A located outside the recess 607, while the step portion of the first epitaxial layer 601A, the light-emitting layer 601B, and the second epitaxial layer 601C are located within the recess 607, therefore, the surface area of the first epitaxial layer 601A is not limited by the aperture area of the recess 607 but can be significantly greater than the aperture area of the recess 607, thereby significantly increasing the area and thickness of the first epitaxial layer 601A; furthermore, due to the fact that merely the light-emitting layer 601B, the second epitaxial layer 601C, and only a part of the first epitaxial layer 601A need to be accommodated in the recess 607, the light-emitting layer 601B and the second epitaxial layer 601C have a larger area and thickness compared to the structure that requires accommodating three layers in the prior art, and thus the area and the thickness of the epitaxial layer 601 are better increased, and the light output is improved. It can also be seen herein that the first epitaxial layer 601A passes through the first electrode 604 (herein is the cathode) from below the first electrode 604, so that the first epitaxial layers 601A of adjacent light-emitting mesas 601 can be connected to each other, and thus in the case of a common-cathode structure (i.e., where the first epitaxial layers of all micro-LEDs in the same array are connected to a common cathode), which can significantly enhance the conductivity between the cathode 604 and the first epitaxial layers 601A compared to the case where it is connected to the cathode 604 solely by the top transparent conductive layer 608 covering it, the conductivity between the cathode 604 and the first epitaxial layer 601A can be significantly enhanced, thereby increasing its power supply. Furthermore, the contact cross-section between the first epitaxial layer 601A and the cathode 604 at the edge is partially planar and partially inclined surface. The inclined surface increases the contact area between the first epitaxial layer 601A and the cathode 604 compared to a vertical surface, and thus the conductivity is increased.

The light-emitting mesa 601 also includes ancillary structures such as passivation layers 612 and 613, a reflective mirror layer 615, and a bottom transparent conductive layer 618 (corresponding to the transparent conductive layer 101 in FIG. 1), etc. The passivation layer 612 is arranged between the light-emitting mesa 601 and the reflective mirror layer 615, and optionally extends on the upper surface of the first insulating layer 611A, and the passivation layer 613 is arranged between the inner wall of the recess 607 and the reflective mirror layer 615, and optionally extends on the upper surface of the first insulating layer 611A. In another embodiment, merely one of the passivation layers 612 and 613 extends on the upper surface of the first insulating layer 611A, or neither of them extends over the upper surface of the first insulating layer 611A, instead, they extend merely until to the upper surface of the first insulating layer 611A, while the upper surface of the first insulating layer 611A is covered by another insulating layer or dielectric layer. The function of passivation layers 612 and 613 is not merely to reduce current leakage at the sidewalls, but also to passivate sidewall defects and block damage to the light-emitting mesa caused by water, oxygen, etc. during operation, and they can also prevent metal diffusion from the reflective mirror layer 615, the cathode 604 etc. to the first insulating layer 611 or the light-emitting mesa 601. The passivation layers 612 and 613 may be formed by depositing SiO₂ material using a CVD process, and also may be formed by depositing Al₂O₃ material using an ALD process. The bottom transparent conductive layer 618 is arranged between the second epitaxial layer 601C and the reflective mirror layer 615. The bottom transparent conductive layer 618 is configured to electrically connect the second epitaxial layer 601C of the light-emitting mesa 601 to the reflective mirror layer 615 and further to the through-hole contact portion 602. The material of the bottom transparent conductive layer 618 is, for example, metal oxide such as indium tin oxide ITO or zinc oxide ZnO, etc., its formation methods include, for example, physical vapor deposition (PVD), chemical vapor deposition (CVD), sol-gel method, solution coating method, etc.

The reflective mirror layer 615 is configured to reflect light from the light-emitting mesa 601 upward. For this purpose, the reflective mirror layer 615 has an inclined surface on the side facing the light-emitting mesa 601, the inclination angle of this surface is, for example, the same as the inclination angle of the light-emitting mesa, of 10° to 85°, preferably 30° to 70°, particularly 35° to 50°.

Herein, the reflective mirror layer 615 includes a side reflective mirror layer 615A and a bottom reflective mirror layer 615B. The side reflective mirror layer 615A covers at least a part of the side surface of the light-emitting mesa 601. Both the side reflective mirror layer 615A and the bottom reflective mirror layer 615B are configured to reflect light from the light-emitting mesa 601 upward, while the bottom reflective mirror layer 615B is also configured to electrically connect the bottom transparent conductive layer 618 with the first through-hole contact portion 602. In the present embodiment, the side reflective mirror layer 615A covers a part of the side surface of the light-emitting mesa 601 within the recess 607, and the side reflective mirror layer 615A is formed between the passivation layer 612 and the inner wall of the recess 607 of the insulating layer. Due to the presence of the passivation layer 612, the side reflective mirror layer 615A may or may not have an atomic layer deposition layer on the side facing the light-emitting mesa 601. In the case of having an atomic layer deposition layer, it is possible to further prevent the metal in the reflective mirror layer 615 from penetrating into the light-emitting mesa 601 through the passivation layer 612. The side reflective mirror layer 615A has an inclined surface on the side facing the light-emitting mesa 601 to reflect light from the light-emitting mesa upward, the inclination angle of the inclined surface is, for example, the same as the inclination angle of the light-emitting mesa 601, of 10° to 85°, preferably 30° to 70°, and especially 35° to 50°. The bottom reflective mirror layer 615B covers at least a part of the bottom surface of the light-emitting mesa 601. In the present embodiment, the bottom mirror 615B covers the bottom transparent conductive layer 618 of the light-emitting mesa 601. The bottom reflective mirror layer 615B has an atomic layer deposition layer on the side facing the light-emitting mesa 601. The atomic layer deposition layer can block metal from the reflective metal layer to prevent its diffusion while substantially not affecting light reflection. For the specific structure of the reflective mirror layer 615, reference may be made to FIGS. 1 and 2 and related description.

The reflective mirror layer may include, from top to bottom (i.e., from the side facing the light-emitting mesa 601 to the side facing away from the light-emitting mesa 601), for example, an atomic layer deposition layer, a reflective metal layer, a first barrier layer, and a second barrier layer, wherein the upper side of the reflective mirror layer faces the light-emitting mesa or epitaxial layer of the micro-LED, and the lower side of the reflective mirror layer faces away from the light-emitting mesa or epitaxial layer of the micro-LED or faces the bottom transparent conductive layer.

For example, the stacked layer structure of the reflective mirror layer 615 is as follows (in an order from close to the light-emitting mesa to far away from the light-emitting mesa):

An atomic layer deposition layer, the material of which is nickel, the thickness is 5 angstroms;

A reflective metal layer, the material of which is silver, the thickness is 1000 angstroms;

A first barrier sublayer and a second barrier sublayer, the material of which is titanium and platinum, the thickness is 200 and 500 angstroms, respectively;

A second barrier layer, the material of which is titanium, the thickness is 200 angstroms.

Furthermore, the number of the first barrier layers is 3.

The reflective mirror layer 615 can be formed, for example, through methods such as evaporation, sputtering, or chemical vapor deposition (CVD), etc., wherein the atomic layer deposition layer of the reflective mirror layer 615 is formed by atomic layer deposition. The thickness of the passivation layer 612 between the reflective mirror layer 612 and the light-emitting mesa 601 is 800 to 2000 angstroms, preferably 600 to 1600 angstroms. The thickness of the passivation layer 613 between the reflective mirror layer 615 and the inner wall of the recess 607 is 200 to 800 angstroms, preferably 300 to 600 angstroms.

In the present disclosure, the bottom transparent conductive layer 618 and the first epitaxial layer 601A (corresponding to the second epitaxial layer 102D in FIG. 1A), the light-emitting layer 601B (corresponding to the light-emitting layer 102B in FIG. 1A), and the second epitaxial layer 601C (corresponding to the first epitaxial layer 102B in FIG. 1A) are etched with inclined side surfaces during different etching steps. For example, in a first etching step, the bottom transparent conductive layer 618 is first etched to form a first inclined edge of the bottom transparent conductive layer 618. Then, in a second etching step, the first epitaxial layer 601A, the light-emitting layer 601B, and the second epitaxial layer 601C are etched to form a second inclined edge of the entire light-emitting mesa 601. The inclination angle of the first inclined edge may be equal to the inclination angle of the second inclined edge, for example both within the range of 55° to 75°, particularly 60° to 70°. Alternatively, the inclination angle of the first inclined edge may be larger, e.g., greater than 70°, particularly greater than 75°, while the second inclined edge may be less than 75°, particularly less than 70°, due to the fact that the thickness of the bottom transparent conductive layer 618 is significantly less than the sum of the thicknesses of the first epitaxial layer 601A, the light-emitting layer 601B, and the second epitaxial layer 601C, therefore, the average of the inclination angle of the first inclined edge and the second inclined edge on the total height of the light-emitting mesa can still fall within the range of 55° to 75°, particularly 60° to 70°. In another case, the first inclined edge and the second inclined edge are not equal to each other, but the inclination angles of the first inclined edge and the second inclined edge are both within the range of 55° to 75°, particularly 60° to 70°. The above optimized inclination angle configuration increases the surface area of the first epitaxial layer 601A of the micro-LED chip, i.e. enhances the aperture ratio, meanwhile, it can also increase the width and area of the light-emitting layer 601B and the second epitaxial layer 601C, thereby improving the overall light output.

The top transparent conductive layer 608 is arranged on the first epitaxial layer 601A and electrically connects the first electrode 604 (cathode) with the first epitaxial layer 601A. Herein, the top transparent conductive layer 608 extends on the first epitaxial layer 601A and fully covers the first epitaxial layer 601A, thereby providing more uniform power supply for the first epitaxial layer 601A. In other embodiments, the top transparent conductive layer 608 may merely partially cover the first epitaxial layer 601A. Furthermore, the top transparent conductive layer 608 extends below the first electrode 604, which is the cathode in this case, such that the top transparent conductive layer 608 extends continuously on the first epitaxial layer 601A of adjacent light-emitting mesas 601A, so that the coverage area for the first epitaxial layer 601A is increased. The material of the top transparent conductive layer 608 is, for example, metal oxide such as indium tin oxide ITO or zinc oxide ZnO, etc. Its formation methods, for example, include physical vapor deposition (PVD), chemical vapor deposition (CVD), sol-gel method, solution coating method, etc.

The first electrode 604, herein is the cathode, which is arranged to surround the light-emitting mesa 601. The cathode 604 and its connecting components may be made of materials such as metals (such as silver, gold, or platinum), graphene, ITO, aluminum doped zinc oxide (AZO) or fluorine doped tin oxide (FTO), or any combination of the above materials. In yet another embodiment of the present disclosure, the cathode 604 and its connecting components may be made of non-transparent or transparent conductive materials, such as indium tin oxide (ITO). In a preferred embodiment, the cathode 604 is made of a reflective metal, so that the cathode 604 can optically isolate adjacent light-emitting mesas 601 from each other and meanwhile also can reflect light from the light-emitting mesas 601, for example, reflecting the light upward to the microlens 605, thereby increasing light output. In another embodiment, a reflective layer, such as a silver layer, may be coated onto the surface of the cathode 604 to provide reflective capability. Herein, the surface of the cathode 604 facing the light-emitting mesa 601A is an inclined surface, and it is inclined towards two sides (i.e. inclined from the bottom surface towards two sides), so that the light falling on it can be reflected upward, i.e. towards the light extraction side. Furthermore, the cathode 604 may be divided into an edge cathode 604A and a central cathode 604B, wherein the edge cathode 604A is arranged between the second electrode 610 (herein is the anode) and the outermost light-emitting mesa 601, wherein a part of the edge cathode 604A is arranged on the passivation layer 612, and another portion is arranged on the top transparent conductive layer 608, while the central cathode 604B is arranged between adjacent light-emitting mesas 601, wherein the central cathode 604B is arranged on the top transparent conductive layer 608. In this way, the edge cathode 604A can completely cover the side surface of the first epitaxial layer 601A and be in electrical contact with it, thereby increasing the electrical contact area between the cathode 604 and the first epitaxial layer 601A.

The first through-hole contact portion 602 is electrically connected with the bottom of the light-emitting mesa 601 and passes through the first insulating layer 611A. The first through-hole contact portion 602 is used for hybrid bonding with the second through-hole contact portion 603, and thereby electrically connecting the bottom of the light-emitting mesa 601, particularly the second epitaxial layer 601C to the second electrode 610 (herein is the anode). The first through-hole contact portion 602 is preferably a cylindrical through-hole, and the inner wall and/or central space is filled with a conductor, such as metallic copper. The diameter of the first through-hole contact portion 602 is of 0.3 to 2 μm, preferably 0.6 to 1.4 μm. The first through-hole contact portion 602 may be planarized at interface B (e.g., through chemical mechanical polishing CMP) to facilitate hybrid bonding with the second through-hole contact portion 603. Furthermore, in order to enhance the bonding strength and improve the conductivity between the first through-hole contact portion 602 and the second through-hole contact portion 603, a first interface metal layer may be arranged at the first aperture of the first through-hole contact portion 602, and the area of the first interface metal layer is greater than the area of the first aperture. Similarly, a second interface metal layer may be arranged at the second aperture of the second through-hole contact portion, and the area of the second interface metal layer is greater than the area of the second aperture. The areas of the first interface metal layer and the second interface metal layer may be equal, or the area of the first interface metal layer may be greater or less than the area of the second interface metal layer. After the first interface metal layer and the second interface metal layer 202 are bonded to each other, the formed bonding surface is greater than the bonding surface formed by directly bonding the first aperture of the first through-hole contact portion 602 and the second aperture 204 of the second through-hole contact portion 603, and thus the bonding strength is enhanced and the conductivity between the first through-hole contact portion 602 and the second through-hole contact portion 603 is improved. The first interface metal layer 201 and the second interface metal layer 202 are made of, for example, a conductive metal such as copper. Their formation methods may include, for example, physical vapor deposition (PVD), chemical vapor deposition (CVD), electroplating, chemical plating, and so on. The formation method of the first through-hole contact portion 602 may be, for example, as follows: a light-emitting mesa 601 and a first insulating layer 611A are formed on a temporary substrate, then the first insulating layer 611A is etched to form through-holes leading to the bottom of the light-emitting mesa 601, subsequently, a metal is deposited in the through-holes, and finally the apertures of the through-holes are planarized to form the bonding surface.

Furthermore, the first through-hole contact portion 602 is used to electrically connect the drive circuit 606 with the bottom (herein is the reflective mirror layer 607) of the epitaxial layer 601 (or light-emitting mesa) of the micro-LED array after bonding with the second through-hole contact portion 603, thereby connecting the epitaxial layer 601 to the anode 610. Herein, a first metal barrier layer 617 is arranged between the through-hole contact portion 602 and the reflective mirror layer 607. The first metal barrier layer 617 can prevent the metal in the first through-hole contact portion 602 from diffusing into the epitaxial layer 601 or the insulating layer 611A through the reflective mirror layer 607 and other layers (e.g., the bottom transparent electrode layer) that may be arranged therebetween, or from oxidizing. If the metal in the first through-hole contact portion 602 diffuses into the epitaxial layer 601, the luminous performance of the epitaxial layer 601 will be affected; if it diffuses into the insulating layer 611A, the insulating effect of the insulating layer 611A will be affected, thereby leading to leakage current or even short circuits; if the metal in the first through-hole contact portion 602 oxidizes, it may cause poor contact between the first through-hole contact portion 602 and the reflective mirror layer 607, or even result in an open circuit in the electrical circuit to the epitaxial layer 601. From this, it can be seen that by arranging the first through-hole contact portion 602 according to the present disclosure, metal diffusion in the first through-hole contact portion 602 can be effectively avoided, and thus risks such as reduced luminous performance, short circuit, and open circuit of the micro-LED can be effectively prevented. The combination of the first metal barrier layer 617 and the first barrier layer 203 and the second barrier layer 204 of the reflective mirror layer can further enhance the metal barrier and antioxidant effects.

The second electrode 610, herein is the anode, and is electrically connected with the drive circuit 606 through a third through-hole contact portion 614 passing through the first insulation layer 611A and the second insulation layer 611B. The anode 610 may be, for example, connected to an external power source or control source to be used to supply power for the micro-LED chip 600 or control the micro-LED chip 600. Herein, the third through-hole contact portion 614 may include a plurality of through-hole contact portions to be used to connect the second epitaxial layers 601C of a plurality of light-emitting mesas to the anode 610. Herein, it is exemplarily shown that the third through-hole contact portion 614 includes two through-hole contact portions, but this is merely an example, and other numbers of through-hole contact portions 614 are also conceivable. The third through-hole contact portion 614 may be formed either before hybrid bonding or after hybrid bonding. If the third through-hole contact portion 614 is formed before hybrid bonding, then the upper and lower portions of the third through-hole contact portion 614 are first formed in the upper stacked layer 600A and the lower stacked layer 600B, respectively, and then after hybrid bonding, these two portions are connected through the through-hole contact portion, and then the first insulating layer 611A is etched from above to form the anode 610 on the third through-hole contact portion 614. If the third through-hole contact portion 614 is formed after hybrid bonding, then the first insulating layer 611A is etched from above to form through-holes leading to the drive circuit 606, metal is then deposited in the through-holes, then the third through-hole contact portion 614 is etched to form a recess, metal is then deposited in the recess to form the anode 610. The anode 610 and its connecting components may be made of materials such as metals (e.g., copper, silver, or aluminum), graphene, ITO, aluminum doped zinc oxide (AZO), or fluorine doped tin oxide (FTO), or any combination of the above materials.

The first bonding mark 609A is arranged in the first insulating layer 611A and exposes the first marking surface, i.e., the aperture of the first bonding mark. The function of the first bonding mark 609A in the upper stacked layer 600A is to serve as a mark aligned with the second bonding mark 609B in the lower stacked layer 600B, and thus precise hybrid bonding is achieved, wherein the second bonding mark 609B is arranged in the second insulating layer 600B and exposes the second marking surface, i.e., the aperture of the second bonding mark. The alignment method of the first bonding mark 609A with the second bonding mark 609B is to align and adhere the first marking surface with the second marking surface during hybrid bonding, at this time, the upper stacked layer 600A and the lower stacked layer 600B have been aligned, and then hybrid bonding can be performed. The first bonding mark 609A and the second bonding mark 609B may be metal through-holes, and the two may be bonded at the interface. Furthermore, the first bonding mark 609A and the second bonding mark 609B may have enlarged apertures and/or the apertures may be coated with a metal layer to facilitate identification of their positions and enhance bonding strength.

The microlens 605 is arranged above the light-emitting mesa 601 for shaping such as focusing or collimating the light emitted therefrom. The microlens includes a lens portion 605A and a spacer portion 605B. The lens portion 605A is arranged at the outermost side, i.e., the topmost and configured to shape light from the light-emitting mesa 601. The spacer portion 605B is arranged between the lens portion 605A and the light-emitting mesa 601 to adjust the focal position of the lens portion 605A, for example, parameters such as the thickness of the spacer portion 605B and the curvature of the lens portion 605A, etc. are adjusted, such that the focal point of the lens portion 605A is precisely located in the light-emitting mesa 601 of the micro-LED. The width of the microlens 605 is, for example, 0.8 to 4 μm. The distance between the lens portion 605A and the cathode 604 is, for example, 0.05 to 4 μm. The microlens 605 corresponds one-to-one with the light-emitting mesa 601. Meanwhile, in the present embodiment, adjacent microlenses 605 have gaps between them and their bottoms are connected with each other. The lens portion 604A is located above the cathode 604. The microlens 605 may be formed through a plurality of deposition steps, during the formation process of the microlens, a SiO₂ film layer is first deposited, then ion etching is performed, and the microlens is formed at the positions on the surface of the top transparent conductive layer 608 corresponding to each light-emitting mesa 601.

Herein, the lens portion 605A of the microlens 605 has an elliptical central longitudinal cross-section. In the present embodiment, the semi-major axis of the ellipse lies within the plane of the upper surface of the spacer portion 605B.

In the present embodiment, the parameters of the microlens 605 are as follows:

The diameter of the upper surface of the light-emitting mesa 601 facing the microlens 605 is n;

The spherical height of the lens portion is a x n (a multiplied by n, the same below);

The curvature radius is m;

The height of the spacer portion is b x n;

The width of the spacer portion is c x n;

The curvature radius of the lens portion is d x m;

wherein a, b, c, m, and n are all positive numbers, and a, b, c, m, and n have the following range of values:

1.2 ≤ a ≤ 1.6, herein: a = 1.43

0.2 ≤ b ≤ 0.3, herein: b = 0.28

0.9 ≤ c ≤ 1.3, herein: c = 1.1;

1.3 μm ≤ m ≤ 1.8 μm, herein: m = 1.54 μm

1.4 μm ≤ n ≤ 1.8 μm, herein: n = 1.6 μm.

Through the aforementioned shape and parameter configuration of the microlens 605, the morphology of the microlens 605 can be optimized, so that the light extraction efficiency of the micro-LED 600 is improved.

### Lower stacked layer

The lower stacked layer 600B includes a second insulating layer 611B, a second through-hole contact portion 603, a drive circuit 606, and a second bonding mark 609B. The various components are described below, respectively.

The second insulating layer 611B is arranged on the drive circuit 606 and is configured to accommodate the second through-hole contact portion 603. The material of the second insulating layer 611B may be, for example, silicon dioxide, silicon nitride, high-k dielectric materials (e.g., hafnium oxide, aluminum oxide, etc.), and so on. The second insulating layer 611B may be, for example, formed on the drive circuit 606 through methods such as thermal oxidation or chemical vapor deposition (CVD), etc. The thickness of the second insulating layer 611B may be, for example, 1 to 3 μm, preferably 2 μm, and more preferably 0.6 to 1.4 μm. Furthermore, the second insulating layer 611B may be planarized at interface B (e.g., through chemical mechanical polishing CMP) to facilitate hybrid bonding with the first insulating layer 611A.

The second insulating layer 611B is transparent to light emitted from the light-emitting mesa 601. In some embodiments, the second insulating layer 611B is made of a dielectric material such as solid inorganic material or plastic material. In some embodiments, the solid inorganic material includes silicon dioxide (SiO₂), aluminum oxide (Al₂O₃), silicon nitride (Si₃N₄), silicon carbide nitride (SiCN), hafnium oxide (HfO₂), tantalum pentoxide (Ta₂O₅), titanium dioxide (TiO₂), zirconium oxide (ZrO₂), lanthanum oxide (La₂O₃), magnesium oxide (MgO), phosphosilicate glass (PSG), boron phosphosilicate glass (BPSG), or any combination thereof. In some embodiments, the plastic material includes polymers such as SU-8, PermiNex, or benzocyclobutene (BCB), or transparent plastics (resins) including spin-on glass (SOG), or adhesive micro resist BCL-1200, or any combination thereof. In some embodiments, the second insulating layer 611B may facilitate the passage of light emitted from the light-emitting mesa 601. In some embodiments, the second insulating layer 611B may include a plurality of portions, such as three embedded dielectric portions and two adhering dielectric portions. The embedded dielectric portions refer to the dielectric layers surrounding each light-emitting diode structure; while the adhering dielectric portions refer to the dielectric layers between two light-emitting diode structures. The embedded dielectric portions and the adhering dielectric portions may have the same or different compositions.

The second through-hole contact portion 603, which passes through the second insulating layer 611B. The second through-hole contact portion 603 is configured to hybrid bond with the first through-hole contact portion 602 at interface B, and thereby electrically connecting the bottom of the light-emitting mesa 601, particularly the second epitaxial layer 601C to the second electrode 610 (herein is the anode). The second through-hole contact portion 603 is preferably a cylindrical through-hole, and the inner wall and/or central space is filled with a conductor, such as metallic copper. The diameter of the second through-hole contact portion 603 is of 0.5 to 2.2 μm, preferably 0.8 to 1.6 μm. The second through-hole contact portion 603 may be planarized at interface B (e.g., through chemical mechanical polishing CMP) to facilitate hybrid bonding with the first through-hole contact portion 602. Furthermore, in order to enhance the bonding strength and improve the conductivity between the second through-hole contact portion 603 and the first through-hole contact portion 602, a second interface metal layer may be arranged at the second aperture of the second through-hole contact portion 603, and the area of the second interface metal layer is greater than the area of the second aperture. Similarly, a first interface metal layer may be arranged at the first aperture of the first through-hole contact portion 602, and the area of the first interface metal layer is greater than the area of the first aperture. The areas of the first interface metal layer and the second interface metal layer may be equal, or the area of the first interface metal layer may be greater or less than the area of the second interface metal layer. After the first interface metal layer and the second interface metal layer are bonded to each other, the formed bonding surface is greater than the bonding surface formed by directly bonding the first aperture of the first through-hole contact portion 602 and the second aperture of the second through-hole contact portion 603, and thus the bonding strength is enhanced and the conductivity between the first through-hole contact portion 602 and the second through-hole contact portion 603 is improved. The first interface metal layer and the second interface metal layer are made of, for example, a conductive metal such as copper. Their formation methods may include, for example, physical vapor deposition (PVD), chemical vapor deposition (CVD), electroplating, chemical plating, and so on. The formation method of the second through-hole contact portion 603 may be, for example, as follows: a drive circuit 606 is provided, then a second insulating layer 611B is formed on the drive circuit 606, then the second insulating layer 611B is etched to form through-holes leading to the top of the drive circuit 606, subsequently, a metal is deposited in the through-holes, and finally the apertures of the through-holes are planarized to form the bonding surface.

Furthermore, the second through-hole contact portion 603 is used to electrically connect the drive circuit 606 with the bottom (herein is the reflective mirror layer 607) of the epitaxial layer 601 (or light-emitting mesa) of the micro-LED array after bonding with the first through-hole contact portion 602, thereby connecting the epitaxial layer 601 to the anode 610. Herein, a first metal barrier layer 617 is arranged between the second through-hole contact portion 603 and the drive circuit 606. The first metal barrier layer 617 can prevent the metal in the second through-hole contact portion 603 from diffusing into the drive circuit 606 or the insulating layer 611B, or from oxidizing. If the metal in the second through-hole contact portion 603 diffuses into the drive circuit 606, then the electrical performance of the drive circuit will be affected, such as causing a short circuit; if it diffuses into the insulating layer 611B, then the insulating effect of the insulating layer 611B will be affected, thereby leading to leakage current or even short circuits; if the metal in the second through-hole contact portion 603 oxidizes, it may cause poor contact between the second through-hole contact portion 603 and the drive circuit 606, or even result in an open circuit in the electrical circuit to the drive circuit 606. From this, it can be seen that by arranging the second through-hole contact portion 603 according to the present disclosure, metal diffusion in the second through-hole contact portion 603 can be effectively avoided, and thus risks such as short circuits or open circuits in the drive circuit 606. The combination of the first metal barrier layer 617 and the first barrier layer 203 and the second barrier layer 204 of the reflective mirror layer can further enhance the metal barrier and antioxidant effects.

The drive circuit 606 is electrically connected with the second through-hole contact portion 603 to electrically connect the second epitaxial layer 601C of the light-emitting mesa 601 to the anode 610. For this purpose, the drive circuit 606 has conductive line layers to be used for interconnecting each second through-hole contact portion 603 to the corresponding anode 610. The drive circuit 606 may be, for example, a thin-film transistor TFT drive circuit and may include 2T1C drive circuit, 3T1C drive circuit, and 5T2C drive circuit. The drive circuit 606 is configured to drive the micro-LEDs, such as controlling the switching on/off and brightness of the micro-LEDs. The drive circuit 606 may include, for example, transistors, capacitors, a conductive line layer, an insulating layer, and a metal layer, etc. The conductive line layer is formed on the substrate and configured to supply power to the micro-LED array. The insulating layer is formed on the conductive line layer, wherein through-holes are arranged in the insulating layer, and through-hole contact portions (e.g., IC copper pillars) are arranged in the through-holes to be used for electrically connecting the conductive line layer with the micro-LED array. The metal layer is used for bonding and electrically contacting the micro-LEDs. The conductive line layer, the metal layer, and the insulating layer may be formed on substrate 601 through deposition methods such as physical vapor deposition (PVD) and chemical vapor deposition (CVD).

The second bonding mark 609B is arranged in the second insulating layer 611B and exposes the second marking surface, i.e., the aperture of the second bonding mark. The function of the second bonding mark 609B in the lower stacked layer 600B is to serve as a mark aligned with the first bonding mark 609A in the upper stacked layer 600A, and thus precise hybrid bonding is achieved. The alignment method of the first bonding mark 609A with the second bonding mark 609B is to align and adhere the first marking surface with the second marking surface during hybrid bonding, at this time, the upper stacked layer 600A and the lower stacked layer 600B have been aligned, and then hybrid bonding can be performed. The first bonding mark 609A and the second bonding mark 609B may be metal through-holes, and the two may be bonded at the interface. Furthermore, the first bonding mark 609A and the second bonding mark 609B may have enlarged apertures and/or the apertures may be coated with a metal layer to facilitate identification of their positions and enhance bonding strength.

After the formation of the lower stacked layer 600A and the upper stacked layer 600B, the lower stacked layer 600A is jointed with the upper stacked layer 600B through hybrid bonding, such that the first through-hole contact portion 602 is bonded with the second through-hole contact portion 603 and the first insulating layer 611A is bonded with the second insulating layer 611B, optionally the first bonding mark 609A is bonded with the second bonding mark 609B, and the upper and lower portions of the third through-hole contact portion 614 are bonded with each other. The present disclosure solves the technical problem encountered in manufacturing upside-down arranged trapezoidal light-emitting mesa with a large upper surface and a small lower surface, i.e., the electrical connection problem of the light-emitting mesa to the driving circuit, by respectively fabricating the upper stacked layer 600A and the lower stacked layer 600B and then jointing them with each other through hybrid bonding. The present disclosure achieves electrical connection of the light-emitting mesa 601 to the drive circuit 606 through hybrid bonding, allowing both the upper stacked layer 600A and the lower stacked layer 600B can be manufactured from the surface opposed to the hybrid bonding surface, i.e., interface B, towards the hybrid bonding surface, so that high-quality conductive structures, such as the first to third through-hole contact portions (such as IC copper pillars) are achieved, and the length of the conductive structure can also be flexibly selected.

An exemplary of the hybrid bonding may include the following two parts:

(1) Dielectric-to-dielectric bonding (i.e., bonding between the first insulating layer 611A and the second insulating layer 611B): at room temperature, extremely flat and smooth dielectric surfaces obtained through chemical mechanical polishing (CMP) are brought into close contact at room temperature after activation through methods such as plasma treatment to achieve preliminary bonding.

(2) Metal-to-metal bonding (i.e., bonding between through-hole contact portions): after completing the dielectric-to-dielectric bonding, the upper and lower stacked layers are heated to 200-400°C for annealing treatment to strengthen the dielectric bonding and promote metal-to-metal bonding, thereby achieving hybrid bonding.

FIG. 8 illustrates a top view schematic diagram of the micro-LED chip 600 according to the present disclosure.

From FIG. 8, it can be seen that the invented micro-LED chip 600 has a plurality of microlenses 605, which have circular contours in the top view, that is to say, the microlenses 605 have circular shapes in the cross-section parallel to the top surface of the light-emitting mesa. The microlenses 605 all have the morphology of the present disclosure and constitute a microlens array. The microlens array can shape the light from the light-emitting mesa to achieve a desired output beam shape or light direction, meanwhile, also redirecting the light to improve the light extraction efficiency of the micro-LED chip 600.

Although some embodiments of the present disclosure have been described in the present application, however, those skilled in the art will appreciate that these embodiments are merely illustrated as examples. Numerous variation schemes, alternative schemes, and improvement schemes may be conceived by those skilled in the art in light of the teachings of the present disclosure without departing from the scope of the present disclosure. The appended claims are intended to define the scope of the present disclosure and thus encompass methods and structures within the scope of these claims themselves and their equivalent variations.

What is claimed is:

1. A microlens for a micro-LED, comprising:
a lens portion, and
a spacer portion arranged between a light-emitting mesa of the micro-LED and the lens portion, wherein the lens portion is arranged on the spacer portion.

2. The microlens according to claim 1, further comprising:
a connection portion arranged between adjacent microlenses and optically connecting the adjacent microlenses.

3. The microlens according to claim 2, wherein a surface of the connection portion facing a light extraction side is curved towards the light extraction side.

4. The microlens according to claim 2, wherein the connection portion is located at 30% to 100% of the height of the spacer portion.

5. The microlens according to claim 2, wherein a highest point of the connection portion is higher than a top of the spacer portion.

6. The microlens according to claim 2, wherein the connection portion is arranged on a reflective electrode, wherein the reflective electrode is arranged around the light-emitting mesa and configured to reflect light from the light-emitting mesa upward.

7. The microlens according to claim 1, wherein a diameter of an upper surface of the light-emitting mesa facing the microlens is n, a spherical height of the lens portion is a x n; a radius of curvature of the lens portion is m, a height of the spacer portion is b x n, and a width of the spacer portion is c x n, wherein a, b, c, m, and n are all positive numbers, wherein:
1.2 ≤ a ≤ 1.6;
0.2 ≤ b ≤ 0.3;
0.9 ≤ c ≤ 1.3; and
1.3 μm ≤ m ≤ 1.8 μm.

8. The microlens according to claim 7, wherein a central longitudinal cross-section of the lens portion is a part of an ellipse, wherein:
1.40 ≤ a ≤ 1.45;
0.25 ≤ b ≤ 0.30;
1.05 ≤ c ≤ 1.10; and
1.50 μm ≤ m ≤ 1.55 μm.

9. The microlens according to claim 8, wherein a major axis or a minor axis of the ellipse is located within a top plane of the spacer portion.

10. The microlens according to claim 8, wherein a major axis or a minor axis of the ellipse is parallel to a top plane of the spacer portion, and the major axis or the minor axis of the ellipse is lower or higher than the top plane of the spacer portion.

11. The microlens according to claim 7, wherein a central longitudinal cross-section of the lens portion is a part of a circle, and:
1.20 ≤ a ≤ 1.30;
0.20 ≤ b ≤ 0.25;
1.22 ≤ c ≤ 1.30; and
1.70 μm ≤ m ≤ 1.75 μm.

12. The microlens according to claim 7, wherein a central longitudinal cross-section of the lens portion perpendicular to the upper surface is a part of a triangle, and:
1.55 ≤ a ≤ 1.60;
0.22 ≤ b ≤ 0.28;
0.90 ≤ c ≤ 1.10; and
1.33 μm ≤ m ≤ 1.40 μm.

13. A micro-LED chip, comprising:
at least one light-emitting mesa configured to emit light; and
at least one microlens according to claim 1, arranged on the at least one light-emitting mesa.

14. The micro-LED chip according to claim 13, wherein the light-emitting mesa comprises:
a transparent conductive layer arranged on a side of the light-emitting mesa facing away from a light extraction side;
a first epitaxial layer arranged between the transparent conductive layer and a light-emitting layer;
the light-emitting layer arranged between the first epitaxial layer and a second epitaxial layer and configured to emit light; and
the second epitaxial layer arranged on a side of the light-emitting mesa facing the light extraction side, wherein an area of the second epitaxial layer is greater than an area of the first epitaxial layer.

15. The micro-LED chip according to claim 14, further comprising:
a reflective mirror layer configured to cover a side surface and a bottom of the light-emitting mesa;
an insulating layer configured to accommodate the light-emitting mesa and through-hole contact portions;
at least one drive circuit comprising a metal layer, wherein the at least one drive circuit is provided with a plurality of the through-hole contact portions, and the through-hole contact portions are electrically connected with the metal layer, and a micro-LED array area is bonded onto the at least one drive circuit through a bottom conductive bonding layer, wherein the at least one drive circuit further comprises a wiring stacked layer below the metal layer, the wiring stacked layer configured to lead out a first electrode;
the first electrode electrically connected with the through-hole contact portions;
a passivation layer covering at least a part of the side surface of the light-emitting mesa;
a top transparent conductive layer arranged on a surface of the passivation layer and in electrical contact with the second epitaxial layer; and
a second electrode arranged on a surface of the top transparent conductive layer.

16. The micro-LED chip according to claim 15, wherein the second electrode is a circular reflective electrode arranged around the light-emitting mesa.

17. The micro-LED chip according to claim 15, wherein:
the insulating layer is made of a material selected from a group consisting of silicon dioxide (SiO₂), aluminum oxide (Al₂O₃), silicon nitride (Si₃N₄), silicon carbide nitride (SiCN), hafnium oxide (HfO₂), tantalum pentoxide (Ta₂O₅), titanium dioxide (TiO₂), zirconium oxide (ZrO₂), lanthanum oxide (La₂O₃), magnesium oxide (MgO), phosphosilicate glass (PSG), boron phosphosilicate glass (BPSG), or any combination thereof; and/or
the metal layer is made of a material selected from a group consisting of aluminum (Al), copper (Cu), tungsten (W), silver (Ag), gold (Au), nickel (Ni), platinum (Pt), tantalum (Ta), and molybdenum (Mo).

18. The micro-LED chip according to claim 15, wherein the through-hole contact portions comprise a first through-hole contact portion and a second through-hole contact portion, and the insulating layers comprise a first insulating layer and a second insulating layer, and the micro-LED chip comprises an upper stacked layer and a lower stacked layer, wherein the upper stacked layer comprises the first insulating layer, the light-emitting mesa, and the first through-hole contact portion, and the lower stacked layer comprises the second insulating layer, the second through-hole contact portion, and the drive circuit, wherein the lower stacked layer is jointed with the upper stacked layer through hybrid bonding, such that the first through-hole contact portion is bonded with the second through-hole contact portion, and the first insulating layer is bonded with the second insulating layer.

19. The micro-LED chip according to claim 15, wherein the reflective mirror layer includes an atomic layer deposition layer on a side of the reflective mirror layer facing the light-emitting mesa, and the atomic layer deposition layer is configured to block metal diffusion in the reflective mirror layer.

20. The micro-LED chip according to claim 19, wherein the reflective mirror layer comprises, starting from a side facing the light-emitting mesa:
the atomic layer deposition layer, made of a material selected from a group consisting of nickel, platinum, titanium, and tantalum;
a reflective metal layer configured to reflect light, the reflective metal layer is made of a material selected from a group consisting of silver, aluminum, and gold;
a first barrier layer comprising at least a first barrier sublayer and a second barrier sublayer, wherein the first barrier sublayer and the second barrier sublayer are made of a material selected from a group consisting of platinum, titanium, and tantalum; and
the second barrier layer, made of a material selected from a group consisting of platinum, titanium, and tantalum.
